(19) United States
(12) Patent Application Publication
(10) Pub. No.: US 2011/0125422 A1
(43) Pub. Date: May 26, 2011

(54) METHOD AND DEVICE FOR MEASURING AND MONITORING

(75) Inventors: Fabio Goncalves Jota, Belo Horizonte (BR); Patricia Romeiro Da Silva Jota, Belo Horizonte (BR); Eduardo Carvalhaes Nobre, Belo Horizonte (BR)

(73) Assignees: UNIVERSIDADE FEDERAL DE MINAS GERAIS UFMG, Belo Horizonte, Minas Gerais (BR); CEMIG DISTRIBUICAO S.A., Belo Horizonte, Minas Gerais (BR)

(21) Appl. No.: 12/677,768

(22) PCT Filed: Sep. 11, 2008
(86) PCT No.: PCT/BR08/00282

§ 371 Date: Jan. 7, 2011

(30) Foreign Application Priority Data
Sep. 11, 2007 (BR) PI0705569-2

(51) Int. Cl. G06F 19/00; G01R 21/00

(52) U.S. Cl. 702/45; 702/61; 702/50

(57) ABSTRACT

A method and device for remotely measuring, monitoring and controlling physical quantities over digital communication networks is provided. The measured quantities are grouped by energy end-uses or type of energy produced. The present patent describes the hardware and software used to perform these measurements, monitoring and control actions. The method and associated devices provide the means to sub-divide the building energy consumption by its end-uses or into cost centers, so as to determine the “specific energy consumption” of each cost center, in terms of kWh/produced unit, kWh/m², kWh/employee, for example. The system comprises four hierarchically interconnected layers. The first layer includes all the equipments and technologies involved in data acquisition (or actuation) in the monitored building. The second layer contains the equipments and the software for grouping the measurements gathered at each sampling instant by their end-use consumption or type of energy produced, which are responsible for storing the acquired data and sending them to a remote database server, via the Internet. The third layer is responsible for the authentication of each connection to the database server coming from the Web-Servers of the monitored buildings. The fourth layer incorporates the equipments and associated functions responsible for the reception, processing and storage of the data coming from all the monitored loads and for the control of the on-line access to these data (given to users with special privileges). The stored data are analyzed and processed by an application program in order to extract from them the relevant information.

The present invention is generally related to devices and methods for remotely measuring, monitoring and controlling physical quantities (grouped by energy end-uses or type of energy produced) over digital communication networks, and more particularly to devices and methods for measuring and monitoring electrical and environmental variables, such as, for example, electrical current and ambient temperature. The present patent describes the hardware and software used to perform these measurements, monitoring and control actions.

With the constant development of the technology, various alternatives have been developed to help consumers to manage the use of energy, water and gas.

In the early installations of energy distribution systems to end users, the consumption measurement of energy has been made with electromechanical meters, since this had been the only viable type of meter. With the evolution of metrological systems, new types of meters, based on electronics technology, began to be used, with a series of technical advantages with respect to traditional meters, mainly to monitor other electrical quantities of interest, and, in many cases, with lesser degree of complexity for industrialization.

Given the constant evolution of the electronics technology in the most diverse areas, it is natural that the metrological systems experienced constant improvements in respect to the characteristics and functions of energy meters.

Some documents of other patents present management energy distribution systems that enable the transmission of information from electronic meters to a central point of the system and, also, the possibility of sending to the meter of new communications, to allow the control of the energy distribution.

The PI0405991 patent describes a remote management system for electric power meters integrated into the secondary voltage distribution. The technology refers to a system of remote management of electric power meters in secondary voltage distribution, more specifically, the equipment records the user consumption, stores this information and sends it to a Data Concentrator, located near the distribution transformer or the substation.

In PI0500644-9, it is presented a technology for remote management of electric energy of the consumers. It consists of a remote management system of electric energy of the consumers, with its own structure and a specific type of remote communication with bi-directional wireless and electrical wires cables for application directly to any class of electricity consumer, capable of managing the consumption, detecting and signalizing fraud, managing from the demand side and detecting and signalizing the lack of energy, combined with a full interactivity with consumers of electricity.

The Model Utility MU7700863-4 describes a system for monitoring the electrical energy supply at low voltage, which continually monitors the supply of energy at low voltage through sensing and transmission units installed at strategic points of electrical power distribution network, identifying and locating the affected area. This information is then transmitted to the operational centers of the power utility company.

The patent EP1379012 describes a meter of water, gas and electricity, integrated into one module, using communication via PLC, allowing the meter reading and making digital transfer to a central remote computer system by using Internet protocol and existing power line infrastructure, using the Internet Protocol.

The present invention differs from the others in the state of the art for making measurements of the electricity consumption in a stratified sectored way according to the type of the electrical load (or even in each electrical equipment) and in the place of interest, while the other held measurement of the consumed electrical power in the main meter only. In addition to the measures of the consumption of electricity, the developed system, known as “End-Uses Monitoring Center” (EUMC), gathers and analyses measurements of various other quantities of interest, provided they be measurable by a sensor, such as air pressure, flow-rate, temperature, relative humidity, the electrical power factor, among others.

The invention described herein has been conceived aiming at the development of a technically and financially viable (low-cost) system for measuring, monitoring and controlling the energy produced or consumed, grouped by its end-uses consumption or type of energy produced, which can be installed in various parts of the monitored buildings, to measure and store the values of electrical quantities and also of some environmental variables (such as, air temperature, humidity, luminosity, radiation, among others). Within the basic considerations of this invention, it is also capable of monitoring, via the Internet, the mentioned variables in each building, uninterruptly, 24 hours a day. A diagram of this end-uses monitoring center is shown in FIG. 1.

The method described in this invention provides the tools needed to accomplish the monitoring of the energy and thermal/luminous performance of the facilities, in a stratified way according to the type of the electrical load considered, allowing an assessment of the critical consumption and how each one affects the performance of the building as a whole. These tools turn possible the sub-division of the building energy consumption by their end-uses or into cost centers, so as to determine the “specific energy consumption” of each cost center, in terms of kWh/produced unit, kWh/m², kWh/employee, for example, thus identifying their performance. This tool, provided by the methods and devices of this invention, helps the energy manager in the productivity increase from the knowledge of the wasting points of energy. In addition, this stratified monitoring in various parts of the building bring the possibility of acting locally thus improving the performance of each part of a building. All the monitored information is turned available to registered users, allowing access to data of each building

The monitoring system is capable of making sectored measurements in the building in pre-defined time intervals. The monitored loads are grouped in cost centers according to their end-use or sector of the building. For example, electricity end uses may be grouped as: air-conditioning, space heating, water heating, lighting, appliance operation, and so on. Air-conditioning loads are measured and stored separately from those of lighting, thus forming cost centers by end-uses; alternatively, the loads may be grouped by the consumption in each floor to build a cost center by sector of the building, and so on.

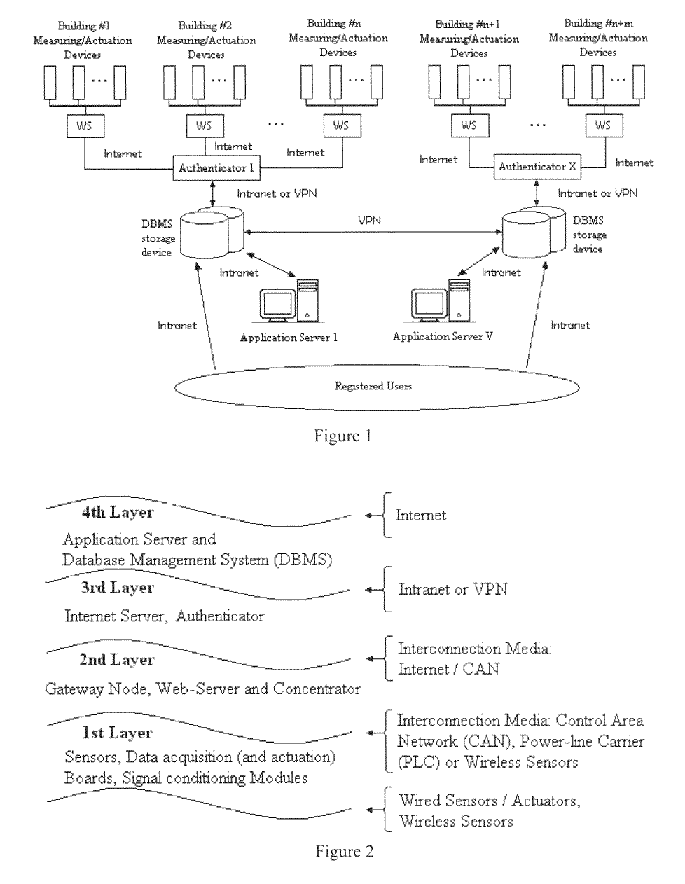

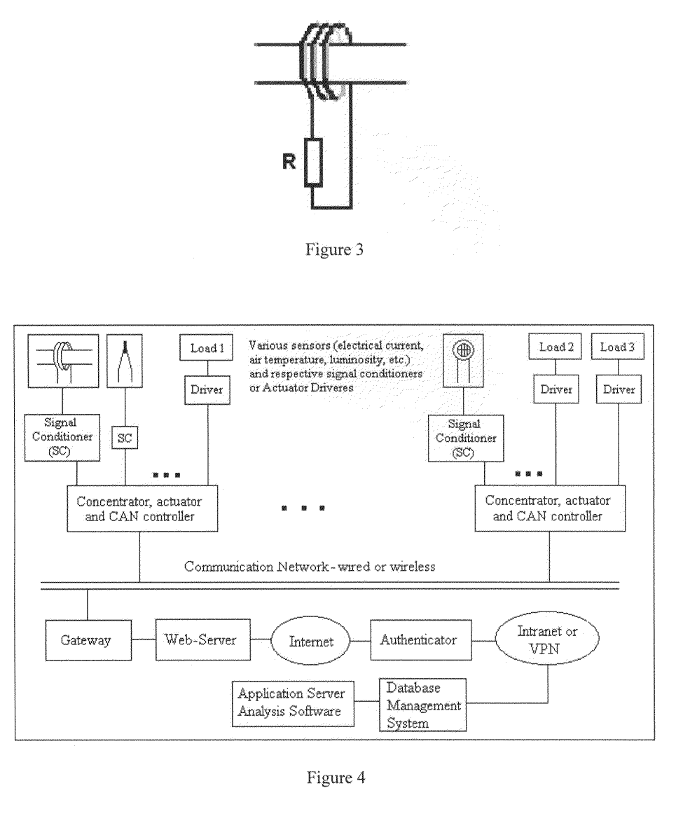

The technology can be divided into four hierarchically interconnected layers, as shown in FIG. 2. The first layer, or the inner layer, includes all the equipments and technologies involved in data acquisition (or actuation) in the building under analysis. This layer is composed of various sensor (or actuator) elements used to measure (or control) the desired variables and loads, comprising a sensor module, a signal conditioning module, a data acquisition module, an actuator module and a driver module, capable of performing simultaneously both functions (measurement and actuation). It is also included signal conditioners and the boards that make the data acquisitions. The maximum current of the load to be monitored is essentially determined by the bus to which this load is connected. Thus, the current transformer used to measure it depends on the current range. For currents up to 50 A, the current is directly measured by a toroidal transformer with current ratio of 500:1. To measure currents above 50 A, an auxiliary current transformer, with secondary current of 5 A, is used together with the toroidal transformer (which measures the secondary current of the auxiliary current transformer). This current analog signal is converted to a voltage analog signal, such that its peak value be between +1 Volt and −1 Volt. This conversion is done by means of a shunt resistor of 100Ω. FIG. 3 shows a schematic drawing of this connection.

This voltage signal is then rectified and converted to a DC value between 0 and 5 Volt (which is the value that can be read by the data acquisition boards). The element responsible for this task is the Signal Conditioner (SC) module (or, for AC voltage and AC current measurement, a Signal Amplifier and Rectifier Module, or simply SARM). The function of SARM is to convert the alternate signal (with peak value not greater than 1 Volt or −1 Volt) in a DC signal with full scale range of 5 Volt. At the end of this signal conversion process, the value of the measured current is expressed in terms its corresponding root means square (RMS) value, which is calculated assuming that the measured current, after conditioning, is sinusoidal.

The data acquisition and control modules are, actually, parts of a communication network, each representing a node of the system, being responsible mainly for the data acquisition and conversion of the signals sent by the SCs (the signal conditioner modules). For monitoring other variables, if the sensing element is able to provide a signal between 0 and 5 Volt DC, the use of a SC is not necessary. Each node card is capable of performing the acquisition of up to seven analog signals and controlling (on or off) up to 3 loads. In each network, up to 128 node cards can be interconnected to each other, meaning that a total of 896 loads can be monitored. The interconnection of the nodes is made using a communication network (wired or wireless), for example, the Computer Area Network or CAN. FIG. 4 presents a diagram showing how the interconnection of various components is done using a communication network.

The first layer further comprises a software responsible for receiving the data from the sensor module (through a SC) and forwarding them, via a router, to the next layer. This software is capable of making sectored measurements at a sampling period of 15 s.

The second layer contains the equipments and the required technologies to make them work properly. They are responsible for, at each sampling cycle, storing the acquired data and sending them to the remote database server. In this layer, a special node of the network, acting as a router (a gateway node), performs the task of interfacing the local network (CAN), mentioned earlier, to the Internet, to which the database server is connected. The gateway node is implemented in a board similar to the ordinary node boards, differing from those only because the serial bus interface is used to connect to a Web-Server, which in turn gets the data from all the node boards (connected to the network) through the gateway node. The Web-Server sends the data to the remote database server, via the Internet.

This second layer further comprises a software for grouping the measurements gathered in each sampling instant by their end-use consumption or type of energy produced. It is also responsible for encapsulating, encrypting and forwarding the information to a remote database server. Besides the actual value of the measured quantity, the software also sends information about the channel and the board from which the quantity has been acquired, as well as the corresponding monitored building. It is also incorporated in the software a facility to prevent loss of information: in the event of a communication failure (between the acquisition system and the database server), the gathered data are locally stored; once this communication is restored, the acquired data are sent to the database server.

The third layer is responsible for the authentication of each connection to the database server coming from the set of Web-Servers (typically, one per monitored building). The database server may be physically distributed in various locations, being in the current stage interconnected through a safe connection (VPN type), as illustrated in FIG. 1. This layer further comprises an Internet server responsible for receiving and authenticating the data coming from the Internet. There is also a software in which the authentication and decryption of the (encrypted) messages takes place, thus validating the connection between the web-servers (of each building) and the database server (in the next layer).

Finally, the fourth and last layer incorporates the equipments and associated functions responsible for the reception, processing and storage of the data coming from all the loads in the monitored buildings. The control of the on-line access to these data (given to users with special privileges) is made in this layer, in which the stored data are analyzed and processed by the application program in order to extract from them the relevant information. This layer comprises the application server and the database server.

In this layer, there is also a software responsible for analyzing some variables, among the stored data, and turning them available, in real time, to the users. A special facility for managing the actuator and driver modules is available, to allow the control of the supplied inputs. For example, from a local or remote (via Internet) command, it is possible to turn on or off a particular load, to fulfill a requirement of the user or even of the power utility company.

Another application of the present invention is the automatic treatment of the data turned available to the building energy managers or Building Energy Conservation Committees (BECC), since the raw measurements, usually, does not provide the necessary information to yield appropriate corrective actions. Since the members of the BECC do not necessarily (and usually do not) have the technical knowledge to understand the data as gathered from various loads and parts of the buildings, the relevant information is extracted and presented to the user in a more appropriate way (trend charts, histograms, real-time plots, correlation and so on).

For this invention, the CAN protocol is used to build the message frames and to implement the functions that are used on the upper communication layers. The message frames comprises, besides the value of the measured quantity, the board (and corresponding channel) in which the measurement has been taken, as well as the building it came from. With the availability of this information in layer 4, the task of inserting the monitored data in the database is accomplished more reliably and in an automatic way. Further, its consistency is first checked and, if necessary, a confirmation of the value sent and its origin is requested. Similarly, the user has at his disposal the facility of controlling a particular loads (turning it on or off, for example).

The MCP2515 integrated circuit is the component responsible for the communication in the CAN bus, controlling the information traffic among the nodes in the network. It is in this device that the address configuration of each node or board connected to the bus and the detection of message errors and assembly of the message frames of the CAN network are made.

The arrival of a message in the CAN bus, either coming from an ordinary node or the gateway, triggers a sequence of processing actions taken by the micro-controller in each node board. One of these messages is the request of a new measurement, which, after been converted to the digital form, is sent to the remote EUMC server. In each monitored building, there is a micro-webserver whose main role is to establish a safe connection to the remote database server. Only registered web-servers are allowed to connect to the EUMC server. To do this, the application program (running in the EUMC server) exchange information with client programs (running in the web-servers) using a cryptographic protocol.

The micro-webserver used in the reported applications is equipped with a 32 bit CPU (a RISC processor), one 100 Mbit/s Ethernet, one USB and two RS-232 ports and with 16 Mbytes SDRAM and 6 Mbytes Flash memory. Its power consumption is typically less than 3 W. The web-server also is responsible for keeping a copy of all the measurements taken in each building until the database server certificates that they are safely stored in the database storage devices.

A database management system, DBMS, provides the functionalities for both the web-servers (which send the measurements gathered in each monitored building) and the users, each with different requirements. The task of the DBMS is to represent the data in a format that is meaningful to the user, irrespective of the way the information has been stored in the database devices.

Apart from being encrypted, the transportation of the data from the origin (measuring point) till the DBMS follows a systematic procedure, a special handshake protocol that is established between the webserver, the EUMC server and the DBMS. Under this protocol, the integrity of the information, as well the details of the source of the measurement and the actual time it was acquired, is checked when it arrives at the EUMC server and it is only sent to the DBMS if it is really consistent. The protocol also makes easier the identification of the source of the information (building, board, channel).

The present invention has been conceived to meet the demand of energy managers of buildings that are developing programs to increase building energy efficiency (the so called Energy Efficiency Programs), in which a through knowledge on how the energy is spent is necessary. The EUMC is a low-cost system, of easy installation and of simple operation. Appropriate sensors of necessary type and range are spread over the building to be monitored, measuring electrical current, voltage and power factor, in all circuits and even equipments where they are needed, as well as measuring environmental variables such as indoors and outdoors temperature and humidity, ambient luminosity, solar radiation, energy generated by distributed sources (such as, photovoltaic), among others. The measurements of power consumption together with environmental variables allow the establishment of cause-effect relations among them, for example, the dependence of the air-conditioning load with the external air temperature and the photovoltaic energy with the solar radiation, and so on. Trend graphs are then used do forecast the air-conditioning consumption and help the energy manager to establish a planning for the whole day.

The energy managers (members of Building Energy Conservation Committees) have access, in real time, through the Wide World Web, to the measured data and graphical representation of comparative analysis (e.g., today-yesterday consumptions), since all registered users can see and analyze the information stored in the database. From this remote access, the user has also at his disposal facilities (resources) to send commands to drive the electrical loads, such as turning on or off an electrical load, or even, changing the speed of a compressor motor, for example.

Therefore, this invention has the advantage of opening up new possibilities for effective monitoring of the energy performance of buildings both from the point-of-view of energy efficiency as thermo-luminous comfort. Besides the possibility of grouping the loads by their end use and according to their location in the building, a method for analyzing the information is provided. Based on statistical (actual) data, the analyses are made available along with the measures made online. The “user” has access to this information from any computer connected to the Internet and with a web-browser installed. Such monitoring, made in continuous and stratified way, allows a more realistic study of the energy matrix of the building for confirmation of efficiency gains, in the manner required by Energy Agencies, providing the means for instantly spotting and eliminating any excessive energy consumption (waste of energy).

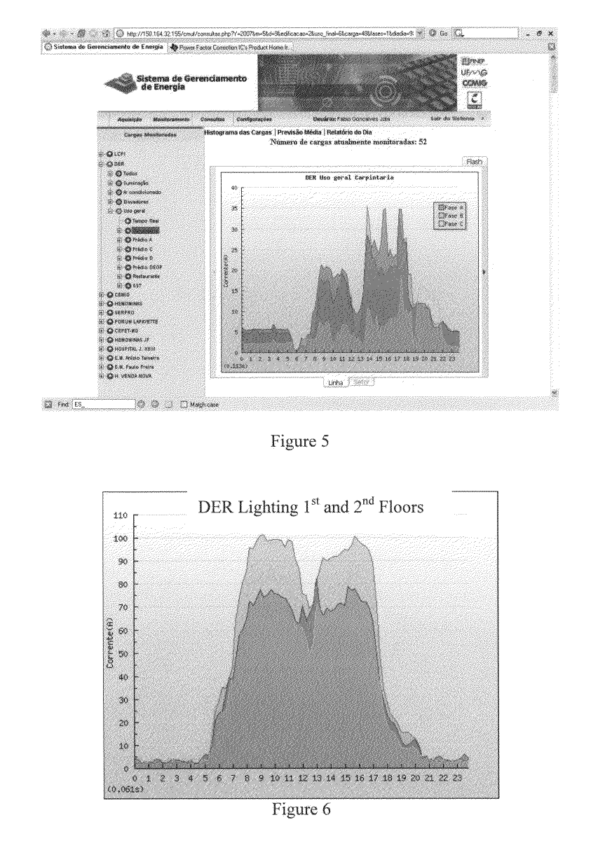

The same occurs when more complex analyses are requested. Special plots and tables are generated by the application program and supplied to the user in a web-page format. Various options have been already implemented to show the data in different formats, such the screens depicted in FIG. 5. These options can be easily incremented, depending on the particular needs of the monitored building. The sampling period should be chosen by the user taking into account the quantity be measured and the desired type of information.

The measuring, monitoring and controlling system of this patent is suitable for applications in residential and commercial buildings, as well as, in industrial plants. It is capable of monitoring the production of electrical energy from various sources, specially the ones inherently distributed (by their nature), namely, wind energy, solar energy (photovoltaic), thermal energy, or even hydro and nuclear energy.

### EXAMPLES

The invention will be better understood by reference to the following examples, which are to be considered as illustrative of the present invention but do not limit the invention described herein. In the following examples, 1 to 3, some possibilities of the End Uses Management Center are demonstrated showing how the EUMC has been used to help consumers to manage the energy and to save energy.

### 1 Description of the Method and of the Devices

A method and device for measuring, monitoring and controlling that comprises a set of equipments sub-divided in four interconnected layers, capable of controlling and grouping various quantities (measurable by a sensor), by end-use consumption or by the type of generated energy.

The first layer comprises the sensor and driver elements used for measuring or controlling the loads and other selected variables. It comprises a sensor module, a signal conditioning module, a command (control) module, a driver module, being able of performing both functions (measurement and control) simultaneously.

The maximum current of the load to be monitored is essentially determined by the bus to which this load is connected. Thus, the current transformer used to measure it depends on the current range. For currents up to 50 A, the current is directly measured by a toroidal transformer with current ratio of 500:1. To measure currents above 50 A, an auxiliary current transformer, with secondary current of 5 A, is used together with the toroidal transformer (which measures the secondary current of the auxiliary current transformer). This current analog signal is converted to a voltage analog signal, such that its peak value be between +1 Volt and −1 Volt. This conversion is done by means of a shunt resistor of 100Ω. FIG. 3 shows a schematic drawing of this connection.

This voltage signal is then rectified and converted to a DC value between 0 and 5 Volt (which is the value that can be read by the data acquisition boards). The element responsible for this task is the Signal Conditioner (SC) module (or, for AC voltage and AC current measurement, a Signal Amplifier and Rectifier Module, or simply SARM). The function of SARM is to convert the alternate signal (with peak value not greater than 1 Volt or −1 Volt) in a DC signal with full scale range of 5 Volt. At the end of this signal conversion process, the value of the measured current is expressed in terms its corresponding root means square (RMS) value, which is calculated assuming that the measured current, after conditioning, is sinusoidal.

The data acquisition and control modules are, actually, parts of a communication network, each representing a node of the system, being responsible mainly for the data acquisition and conversion of the signals sent by the SCs (the signal conditioner modules). For monitoring other variables, if the sensing element is able to provide a signal between 0 and 5 Volt DC, the use of a SC is not necessary. Each node card is capable of performing the acquisition of up to seven analog signals and controlling (on or off) up to 3 loads. In each network, up to 128 node cards can be interconnected to each other, meaning that a total of 896 loads can be monitored. The interconnection of the nodes is made using a communication network (wired or wireless), for example, the Computer Area Network or CAN. FIG. 4 presents a diagram showing how the interconnection of various components is done using a communication network.

The first layer further comprises a software responsible for receiving the data from the sensor module (through a SC) and forwarding them, via a router, to the next layer. This software is capable of making sectored measurements at a sampling period of 15 s.

The second layer contains the equipments and the required technologies to make them work properly. They are responsible for, at each sampling cycle, storing the acquired data and sending them to the remote database server. In this layer, a special node of the network, acting as a router (a gateway node), performs the task of interfacing the local network (CAN), mentioned earlier, to the Internet, to which the database server is connected. The gateway node is implemented in a board similar to the ordinary node boards, differing from those only because the serial bus interface is used to connect to a Web-Server, which in turn gets the data from all the node boards (connected to the network) through the gateway node. The Web-Server sends the data to the remote database server, via the Internet.

This second layer further comprises a software for grouping the measurements gathered in each sampling instant by their end-use consumption or type of energy produced. It is also responsible for encapsulating, encrypting and forwarding the information to a remote database server. Besides the actual value of the measured quantity, the software also sends information about the channel and the board from which the quantity has been acquired, as well as the corresponding monitored building. It is also incorporated in the software a facility to prevent loss of information: in the event of a communication failure (between the acquisition system and the database server), the gathered data are locally stored; once this communication is restored, the acquired data are sent to the database server.

The third layer is responsible for the authentication of each connection to the database server coming from the Web-Servers of the monitored buildings. The database server may be physically distributed in various locations, being in the current stage interconnected through a safe connection (VPN type), as illustrated in FIG. 1. This layer further comprises an Internet server responsible for receiving and authenticating the data coming from the Internet. There is also a software in which the authentication and decryption of the (encrypted) messages takes place, thus validating the connection between the web-servers (of each building) and the database server (in the next layer).

Finally, the fourth and last layer incorporates the equipments and associated functions responsible for the reception, processing and storage of the data coming from all the loads in the monitored buildings. The control of the on-line access to these data (given to users with special privileges) is made in this layer, in which the stored data are analyzed and processed by the application program in order to extract from them the relevant information. This layer comprises the set of web-servers (typically, one per monitored building), the application server and the database server.

In this layer, there is also a software responsible for analyzing some variables, among the stored data, and turning them available, in real time, to the users. A special facility for managing the actuator and driver modules is available, to allow the control of the supplied inputs. For example, from a local or remote (via Internet) command, it is possible to turn on or off a particular load, to fulfill a requirement of the user or even of the power utility company.

### 2 Measuring Examples

### Example A

### Roads Department of the Minas Gerais State—DER-MG

The headquarters of the Roads Department of the Minas Gerais State—DER-MG—is a complex of buildings with different characteristics. After a few meetings and visits of the technical team of the EUMS project with the company representatives, the more relevant electrical loads to be monitored were determined, and grouped by energy end uses. Among them, there are the cost centers based on energy end uses such as: lighting, elevators and air conditioning and the cost centers based on special building sectors such as: the restaurant, the carpentry workshop, the building of the Department of Public Works (DEOP), etc. . . . .

Analysis of loading between phases—An analysis of the data gathered by the apparatus described in this invention, after been installed in the headquarters of the DER building, demonstrated that there was an unbalance in the phase currents of the 1^{st} and 2^{nd} floors circuits. FIG. 6 shows one of the analysis options (load/daily) the user has at his disposal and the type of output selected (line graph). With this analysis option, it is possible to check the electrical current unbalance, determining the times of the day it occurs, thus helping the energy manager to redistribute the loads. The technicians of DER reported frequent electrical disruption due to phase C overload, as shown in FIG. 6.

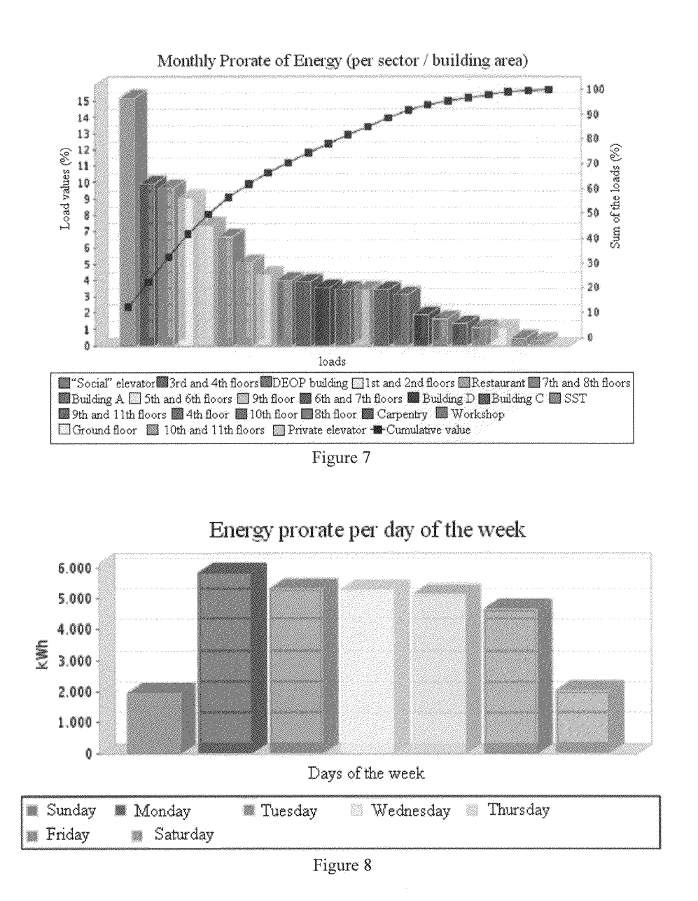

In the case of DER building, 24 loads/sectors (three-phase circuits) are being measured in various parts of the building. A prorated energy, in reference to all the loads, can be requested as an option (rate of daily energy consumption per all loads) with some choices of graphical outputs. FIG. 7 illustrates the result with a bar graph selected as the graphical output. It is observed, in this figure, that 6 of the 24 loads/sectors account for 50% of the consumed energy. Among these loads, it is worth of noting the three air-conditioning systems. One of the loads responsible for the highest energy consumption is the DEOP building that does not belong to the DER; it is simply an independent department that uses the facilities of the DER. The tools provided by this invention allow the calculation of the energy consumed by the DEOP, as well as its electrical demand, thus the determination of the payment for the prorated bill, by taking into account all the loads of the building. The energy consumption can also be prorated according to the day of the week, from which the amount of energy spent during the week can be compared to the total. FIG. 8 illustrate this analysis option showing that, in this building, there is an excessive energy consumption during the weekends.

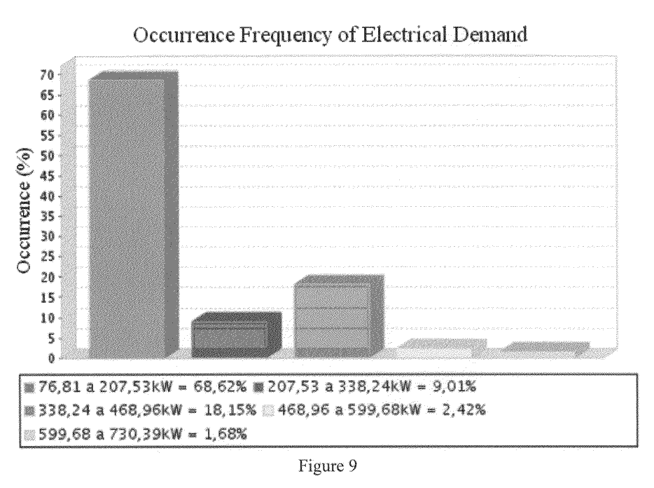

Analysis of the Frequency of Occurrence—The energy supply contract is based on the profiles of maximum demand calculated in a monthly basis. Nevertheless, only a histogram of the occurrence frequency of actual demands is capable of indicating the percentage of occurrences in the selected ranges, as exemplified in FIG. 9. Looking at the data in this figure, it becomes clear that the greatest demand range presents an occurrence percentage of only 1.68% considering all demands of the analyzed month. As the contracted demand is fixed just to attend the highest range, it can be concluded that the contracted demand could be lowered, with the aid of a simple demand controller or even with the introduction of administrative procedures. In the given example, the contracted demand could be reduced from the current 730 kW to as little as 470 kW.

Stand-By Consumption—An analysis of the daily load profiles of the air-conditioning of DER indicates that the current values in stand-by modes (about 88 A) are relatively high. Considering the total energy consumption, in the period of twelve months, the stand-by mode represents 46% of the energy spent in the floors where it is more used and 73% in the higher floors (where the air-conditioning is less used).

### Example B

### Center for Hematology and Hemoterapy of the State of Minas Gerais—HEMOMINAS

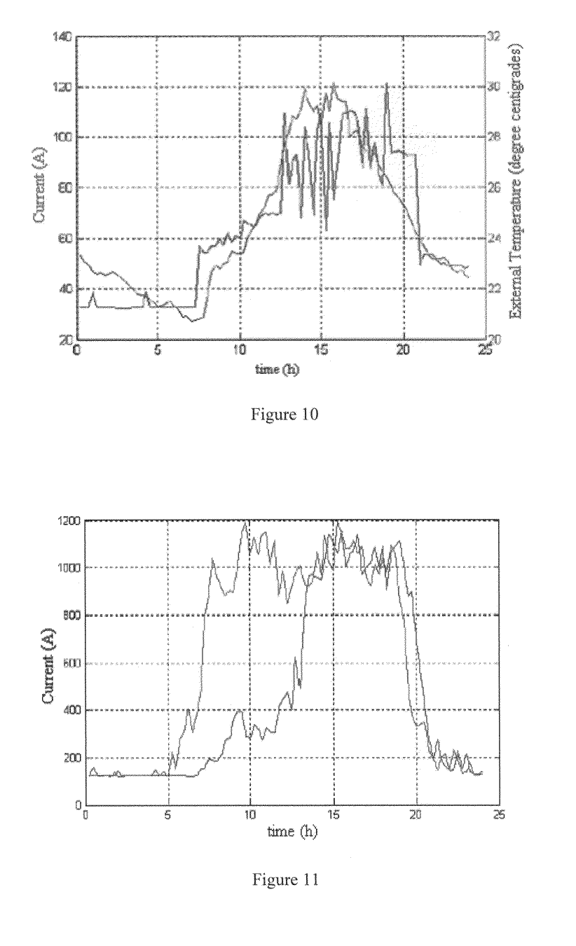

Another building being monitored is the Center for Hematology and Hemoterapy of the State of Minas Gerais—Hemominas. This unit is the largest central collection and processing of blood and blood derivatives of the State of Minas Gerais. The use of energy is more intense in air-conditioned environments in the spaces used for collection and processing of blood and in cold chambers for storage of products. Changes in inventories and in the external temperature have substantial impact on these loads. To check the influence of the outdoor temperature, the EUMC provides special routines in which a correlation between the load and the air temperature is established. FIG. 10 shows the change in the load of Chiller 1 as a function of the variation in outside air temperature as collected and stored by the devices and systems of this invention.

### Example C

### CEMIG Headquarter Building

Currently, the energy consumption of the headquarter building of CEMIG (the largest energy utility in the State of Minas Gerais) is recorded by three commercial meters (model ELO.2113). Each one of them is responsible for measuring different loads or independent sectors. Despite this stratification, the analysis of the use of energy is complicated because of the impossibility of identifying, from the available subdivision, the share of each end use in the composition of the load curves obtained by the meters. The equipments of the invention were installed in this building and, together with the existing meters, have been enabling a more detailed study of the effects of loads monitored in the electrical demand and in the energy consumption of the building.

To start the monitoring process through the invention, the CEMIG energy manager chose the electrical load of the lifts as the object of study in the EUMC project. They are in all eleven elevators and they are considered, along with the loads of air-conditioning system, the largest consumer of energy in the building. There is also a doubt regarding the power factor of this load and, in some situations, there may be problems of low power factor.

In the present invention, the power factor is determined from the electrical measurements of current and voltage, taking at a sampling rate of 3.84 kHz. From the sampled values of instantaneous current and voltage, the instantaneous electrical power is calculated, as well as, the average power and the corresponding RMS values of the current and the voltage. The power factor is then calculated by the ratio of the active power to the apparent power.

FIG. 11 illustrates the profile of the daily current variation of the lift electrical load on two Wednesdays, where one was the Ash Wednesday (1 Mar. 2006) when the working hour starts only at midday.

1. A Method and Device for Measuring and Monitoring, comprising a set of devices sub-divided in four interconnected layers, capable of controlling and grouping of the energy consumption by its end use from any quantity measured by sensor.

2. A Method and Device for Measuring and Monitoring, comprising a set of devices sub-divided in four interconnected layers, capable of grouping the various sources of generated energy by its type from any quantity measured by sensor.

3. The Method and Device for Measuring and Monitoring, of claims 1 and 2, wherein the first layer include at least one sensor module, a signal conditioning module, a data acquisition module, a command and actuation module and a driver module capable of performing both functions simultaneously.

4. The Method and Device for Measuring and Monitoring of claim 3, further comprising, at least, one data acquisition board.

5. The Method and Device for Measuring and Monitoring of claim 3, wherein the current of the monitored load, whose full-scale range is determined by the capacity of the feeding bus, is measured by an arrangement of current transformers of corresponding range.

6. The Method and Device for Measuring and Monitoring of claim 3, further comprising a software for measuring and monitoring physical quantities stratified by sector.

7. The Method and Device for Measuring and Monitoring of claim 6, wherein the data received from the sensor module are forwarded to the Gateway Node.

8. The Method and Device for Measuring and Monitoring of claim 7 characterized by taking stratified sectored measurements at intervals of time from 15 seconds.

9. The Method and Device for Measuring and Monitoring of claims 1 and 2, wherein the second layer comprises a Web-Server and a Gateway board responsible for the interconnection of the local CAN bus to the Internet.

10. The Method and Device for Measuring and Monitoring of claim 9, further comprising a software for grouping the gathered data in each sampling cycle according to the consumption end-use of the type and origin of the energy source.

11. The Method and Device for Measuring and Monitoring of claim 10, wherein the gathered data, after being encapsulated and encrypted, are sent to a remote database server.

12. The Method and Device for Measuring and Monitoring of claim 10, characterized by incorporating to the measured value additional information about the board and the channel in which the quantity has been read and the building of origin of the measurement.

13. The Method and Device for Measuring and Monitoring of claim 10, further comprising a local buffer to locally store the sampled data in the event of failure of communication with the remote server and sent them to the database server just after the restoration of the connection.

14. The Method and Device for Measuring and Monitoring of claims 1 and 2, wherein the third layer comprises an Internet server for authentication and reception of the data sent via the Internet.

15. The Method and Device for Measuring and Monitoring of claim 14, further comprising a software to decode and authenticate the connection of the web-server of each monitored building to the database server.

16. The Method and Device for Measuring and Monitoring of claims 1 and 2, wherein the fourth layer comprises a database server for storing the measured quantities and an application server that allows online access to the data and performs a number of application functions for processing of the stored information.

17. The Method and Device for Measuring and Monitoring of claim 16, comprising a software for monitoring, in real time, the selected variables.

18. The Method and Device for Measuring and Monitoring of claim 17, further comprising an actuator module and a driver module for managing the supply of inputs, by means of a local or an Internet (remote) command.

19. The Method and Device for Measuring and Monitoring of claim 17, wherein the stored data can, from an user command, be presented in graphical form, in real time.

20. The Method and Device for Measuring and Monitoring of claim 17, further comprising an analysis tool that allows the comparison of profiles of any measured quantity obtained on different days or of different clusters (grouped by their end-use or type).

21. The Method and Device for Measuring and Monitoring of claim 17, wherein the performance of the monitored plant, as a whole, is assessed and the critical points are identified.

22. The Method and Device for Measuring and Monitoring of claim 17, further comprising an analysis tool for characterizing the monitored plant by cause-and-effect relations between the consumption or production of energy and the environmental or load conditions.

23. The Method and Device for Measuring and Monitoring of claims 1 and 2, wherein the electrical quantities to be measured are current, voltage and electrical power factor.

24. The Method and Device for Measuring and Monitoring of claims 1 and 2, wherein the environmental quantities to be measured are air flow, pressure, temperature, relative humidity, luminosity and atmospheric pressure.

25. The Method and Device for Measuring and Monitoring of claims 1 and 2, characterized by having the necessary characteristics to be implemented in residential buildings.

26. The Method and Device for Measuring and Monitoring of claims 1 and 2, characterized by having the necessary characteristics to be implemented in commercial buildings.

27. The Method and Device for Measuring and Monitoring of claims 1 and 2, characterized by having the necessary characteristics to be implemented in industrial installations and buildings.

28. The Method and Device for Measuring and Monitoring of claims 1 and 2, characterized by having the necessary specifications for monitoring the production of electricity generated from wind.

29. The Method and Device for Measuring and Monitoring of claims 1 and 2, characterized by having the necessary specifications for monitoring the production of electricity generated from solar photovoltaic cells.

30. The Method and Device for Measuring and Monitoring of claims 1 and 2, characterized by having the necessary specifications for monitoring the production of electricity generated from the thermal-energy.

31. The Method and Device for Measuring and Monitoring of claims 1 and 2, characterized by having the necessary specifications for monitoring the production of electricity generated from hydro-energy.

32. The Method and Device for Measuring and Monitoring of claims 1 and 2, characterized by having the necessary specifications for monitoring the production of electricity generated from nuclear energy.

33. A Device for Measuring and Monitoring comprising a set of equipments divided in two interconnected layers.

34. The Device for Measuring and Monitoring of claim 33, wherein the first layer includes, at least, one sensor module, a signal conditioning module, a data acquisition module, a command and actuator module and a driver module, being able to accomplish simultaneously both functions.

35. The Device for Measuring and Monitoring of claim 34, further comprising, at least, one data acquisition board connected to a communication network.

36. The Device for Measuring and Monitoring of claim 34, further comprising an arrangement of current transformers wherein the full-scale of the current of the monitored load is determined by the capacity of the feeding bus.

37. The Device for Measuring and Monitoring of claim 33, wherein the second layer comprises a Web-Server and a Gateway board responsible for the interconnection of the local CAN bus to the Internet.
